(19) United States
(12) Patent Application Publication
(10) Pub. No.: US 2019/0178936 A1
(43) Pub. Date: Jun. 13, 2019

(54) Pin Conduction Detection System For Connector Slot Of Circuit Board, And Method Thereof

(71) Applicants: Inventec (Pudong) Technology Corporation, Shanghai (CN); Inventec Corporation, Taipei City (TW)

(72) Inventor: Chang-Qing Mu, Shanghai (CN)

(21) Appl. No.: 16/009,845

(22) Filed: Jun. 15, 2018

(30) Foreign Application Priority Data
Dec. 8, 2017 (CN) 201711292332.1

(51) Int. Cl. G01R 31/3187

(52) U.S. Cl. CPC G01R 31/3187

(57) ABSTRACT

A pin conduction detection system for connector slot of circuit board, and a method thereof are disclosed. A connector slot detection circuit board is plugged on a connector slot of a to-be-detected circuit board, and the connector slot detection circuit boards including different types of connector slots are concatenated with each other. A TAP controller can set a JTAG chip of the connector slot detection circuit board to be in a boundary scan mode, and the JTAG chip can read at least one detection signal corresponding to at least one detection pin of the connector slot connector via one of a ADC, a microprocessor, and a switch, so that the TAP controller can perform an conduction detection on the pin of the connector slot corresponding to the detection signal. As a result, test efficiency and coverage rate of testing the connector slot of the circuit board can be improved.

### CROSS-REFERENCE TO RELATED APPLICATION

This application claims the benefit of Chinese Patent Application No. 201711292332.1, filed Dec. 8, 2017.

### BACKGROUND OF THE INVENTION

### 1. Field of the Invention

The present invention generally relates to a detection system and a method thereof, more particularly to a system capable of detecting conduction of different types of connector slots concatenated with each other, and a method thereof.

### 2. Description of the Related Art

The conventional manner of detecting conduction of a slot on a circuit board is to plug a specific test circuit board on a to-be-detected connector slot corresponding thereto, for example, a DIMM test circuit board is plugged on a DIMM slot, a PCI-E test circuit board is plugged on a PCI-E slot, and so on. The test circuit board detects conduction of the slot on the circuit board through a boundary scan technology.

However, the test circuit boards corresponding to different connector slots are different in design, that is, these test circuit boards may perform different detection methods in the detection process through boundary scan; for this reason, in general, the same type of connector slots are concatenated with each other to perform boundary scan for test. However, since a test access port (TAP) controller can provide a limited number of test ports, when the connector slot detection circuit boards including different types of connector slots test the to-be-detected connector slots corresponding thereto, the test ports provided by the TAP controller may be insufficient for above-mentioned test, and it affects test efficiency and the test coverage.

Therefore, what is needed is to develop an improved technical solution to solve the conventional problem that insufficient test efficiency and coverage for connector slot test on the circuit board.

### SUMMARY OF THE INVENTION

In order to solve the problem that insufficient test efficiency and coverage for connector slot test on the circuit board in a conventional manner, the present invention provides a pin conduction detection system for connector slot of circuit board, and a method thereof.

According to an embodiment, the present invention provides a pin conduction detection system for connector slot of circuit board, and the system comprises a to-be-detected circuit board including at least one connector slot, two connector slot detection circuit boards, and a test access port (TAP) controller.

Each of the two connector slot detection circuit boards comprises a connector slot connector, an input joint test action group (JTAG) connector, an output JTAG connector, a JTAG chip, and one of a microprocessor (MCU), at least one analog to digital converter (ADC) and a switch. The at least one ADC or the microprocessor is electrically connected to the connector slot connector and the JTAG chip. The switch is electrically connected to the connector slot connector, the JTAG chip, and the input JTAG connector. The JTAG chip is electrically connected to the input JTAG connector and the output JTAG connector.

The TAP controller is electrically connected to the input JTAG connector of one of the two connector slot detection circuit boards. The one of the two connector slot detection circuit boards is plugged on the at least one connector slot of the to-be-detected circuit board via its connector slot connector.

The output JTAG connector of the one of the two connector slot detection circuit boards is electrically connected to the input JTAG connector of the other of the two connector slot detection circuit boards. The output JTAG connector of the other of the two connector slot detection circuit boards is used for series connection. The TAP controller is configured to set the JTAG chip of the one of the two connector slot detection circuit boards to be in a boundary scan mode, and transmit a control signal to the JTAG chip of the one of the two connector slot detection circuit boards, and the JTAG chip of the one of the two connector slot detection circuit boards reads at least one detection signal corresponding to at least one detection pin of the connector slot connector via the one of the microprocessor, the at least one ADC and the switch. According to the at least one detection signal provided by the JTAG chip of the one of the two connector slot detection circuit boards, the TAP controller performs a conduction detection on at least one pin of the connector slot corresponding to the at least one detection signal.

According to an embodiment, the present invention provides a pin conduction detection method for connector slot of circuit board, and the pin conduction detection method comprises following steps.

First, a to-be-detected circuit board comprising at least one connector slot is provided. Next, two connector slot detection circuit board are provided, wherein each connector slot detection circuit board comprises a connector slot connector, an input JTAG connector, an output JTAG connector, a JTAG chip, and one of a microprocessor, at least one ADC and a switch, and the at least one ADC or the microprocessor is electrically connected to the connector slot connector and the JTAG chip, and the switch is electrically connected to the connector slot connector, the JTAG chip and the input JTAG connector, and the JTAG chip is electrically connected to the input JTAG connector and the output JTAG connector. Next, the TAP controller is provided, and the TAP controller is electrically connected to the input JTAG connector of one of the two connector slot detection circuit boards. The output JTAG connector of the one of the two connector slot detection circuit boards is electrically connected to the input JTAG connector of the other of the two connector slot detection circuit boards. The one of the two connector slot detection circuit boards is plugged on the at least one connector slot of the to-be-detected circuit board via its connector slot connector. The TAP controller is configured to set the JTAG chip of the one of the two connector slot detection circuit boards to be in a boundary scan mode, and transmit a control signal to the JTAG chip of the one of the two connector slot detection circuit boards, and the JTAG chip of the one of the two connector slot detection circuit boards reads at least one detection signal corresponding to at least one detection pin of the connector slot connector via the one of the microprocessor, the at least one ADC and the switch. According to the at least one detection signal provided by the JTAG chip of the one of the two connector slot detection circuit boards, the TAP controller performs a conduction detection on at least one pin of the connector slot corresponding to the at least one detection signal.

According to above-mentioned content, the difference between the technology of the present invention and conventional technology is that, in the system and method of the present invention, the connector slot detection circuit board is plugged on the connector slot of the to-be-detected circuit board, and the connector slot detection circuit boards including different types of connector slots are concatenated with each other, and the TAP controller can set the JTAG chip of the one of the two connector slot detection circuit boards to be in the boundary scan mode, the JTAG chip of the one of the two connector slot detection circuit boards can read at least one detection signal corresponding to at least one detection pin of the connector slot connector via the one of the ADC, the microprocessor and the switch; and, according to the at least one detection signal provided by the JTAG chip of the one of the two connector slot detection circuit boards, the TAP controller can perform a conduction detection on the at least one pin of the connector slot corresponding to the at least one detection signal.

By using aforementioned technical means, the system and method of the present invention can achieve improvement in test efficiency and coverage rate for the connector slot of the circuit board.

### BRIEF DESCRIPTION OF THE DRAWINGS

The structure, operating principle and effects of the present disclosure will be described in detail by way of various embodiments which are illustrated in the accompanying drawings.

FIG. 1 is a block diagram of a pin conduction detection system for connector slot of circuit board, according to an embodiment of the present invention.

FIG. 2 is a flow chart of a pin conduction detection method for connector slot of circuit board, according to an embodiment of the present invention.

FIGS. 3A to 3C are block diagrams of connector slot detection circuit boards for detecting conduction of at least one pin of a connector slot of a circuit board, according to embodiments of the present invention.

### DETAILED DESCRIPTION OF THE PREFERRED EMBODIMENTS

The following embodiments of the present disclosure are herein described in detail with reference to the accompanying drawings. These drawings show specific examples of the embodiments of the present disclosure. It is to be understood that these embodiments are exemplary implementations and are not to be construed as limiting the scope of the present disclosure in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be understood that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise” and variations such as “comprises” or “comprising”, will be understood to imply the inclusion of stated elements but not the exclusion of any other elements.

The embodiments of the present invention are described with reference to the accompanying drawings. A more complete appreciation of the present invention, and many of the attendant advantages thereof, will be readily apparent as the same becomes better understood by reference to the following detailed description when considered in conjunction with the accompanying drawings.

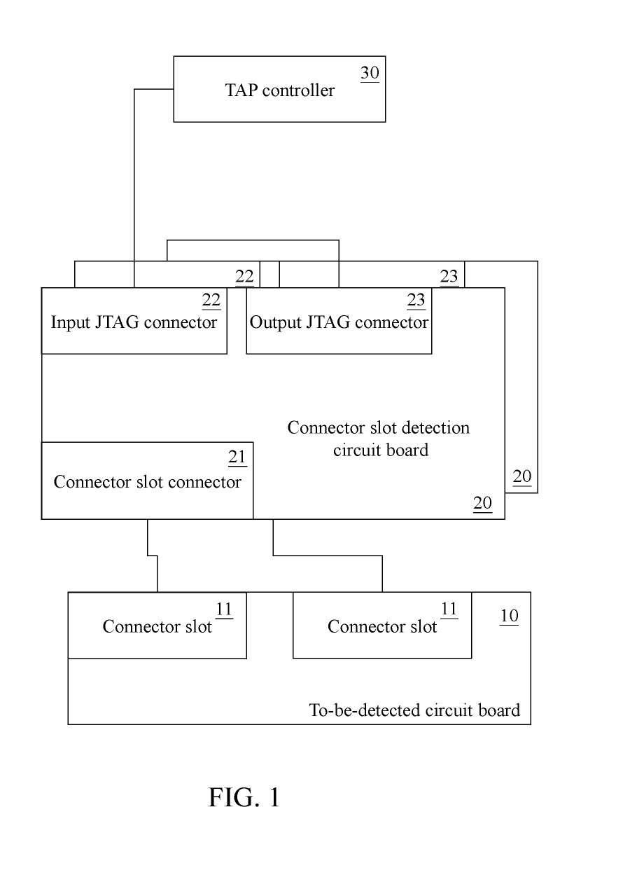

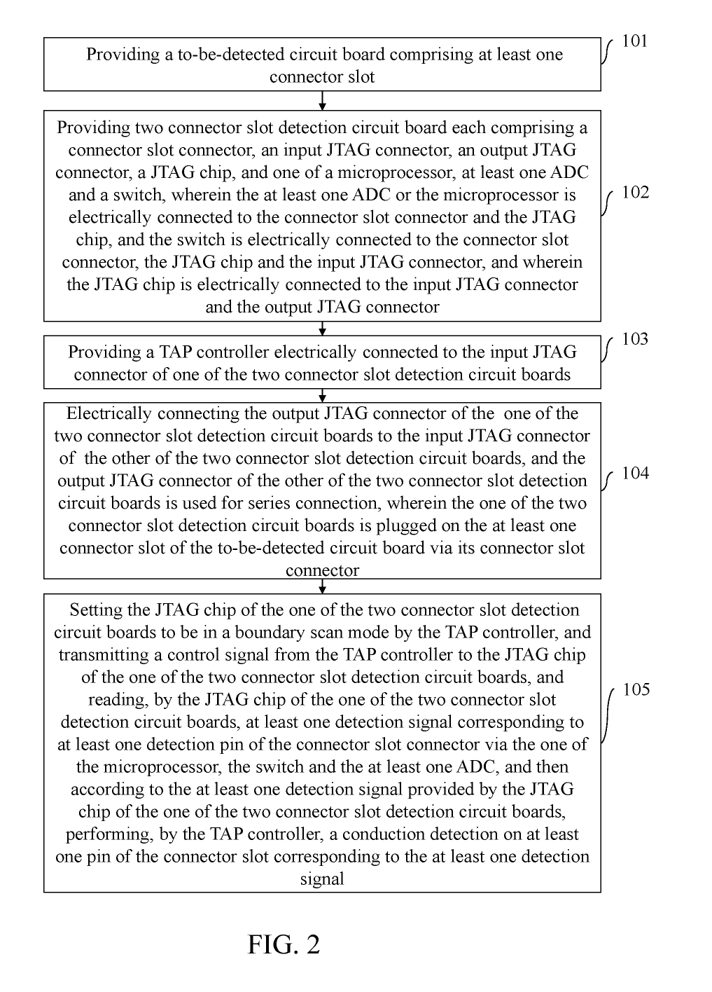

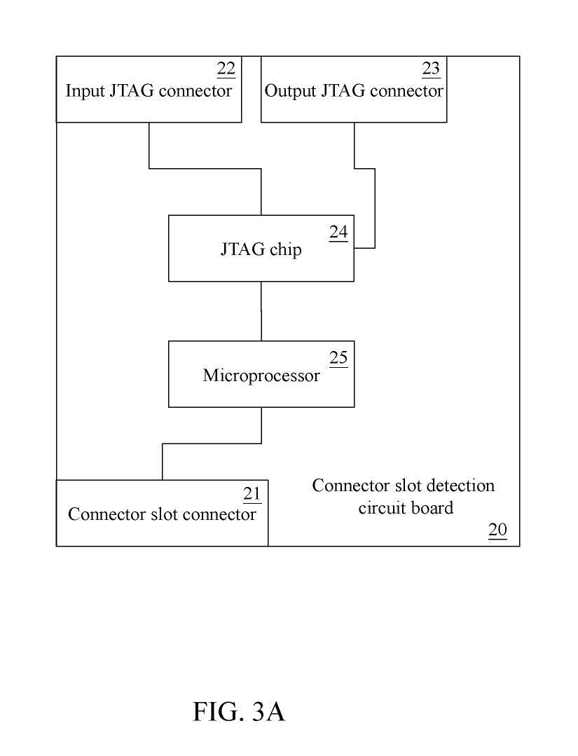

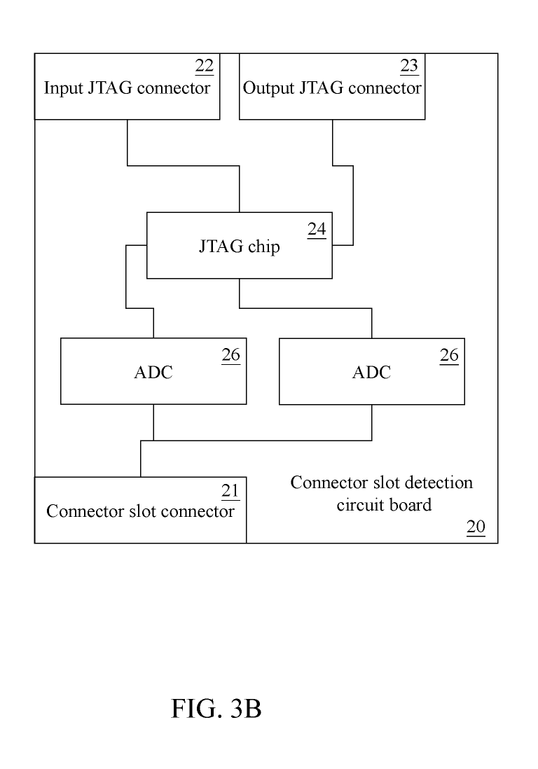

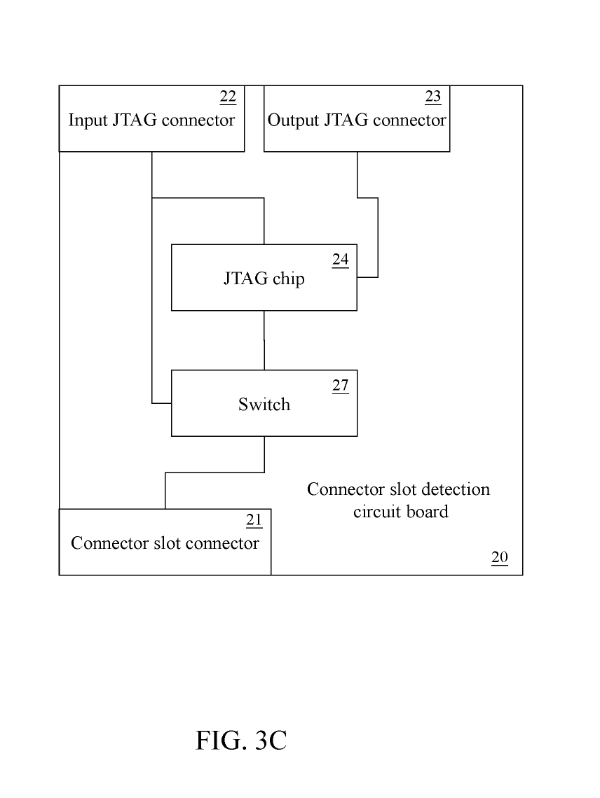

The embodiments below are used to illustrate operations of the system and the method of the present invention. Please refer to FIGS. 1, 2, and 3A to 3C. FIG. 1 is a block diagram of a pin conduction detection system for connector slot of circuit board, according to an embodiment of the present invention. FIG. 2 is a flow chart of a pin conduction detection method for connector slot of circuit board, according to an embodiment of the present invention. FIGS. 3A to 3C are block diagrams of connector slot detection circuit boards for detecting conduction of at least one pin of a connector slot of a circuit board, according to embodiments of the present invention.

The present invention provides a pin conduction detection system for connector slot of circuit board, and a method thereof. The method comprises steps 101 to 105. In the step 101, the system is provided with a to-be-detected circuit board 10 having at least one connector slot 11, two connector slot detection circuit boards 20, and a TAP controller 30. In some embodiments, the at least one connector slot 11 can comprise at least one dual in-line memory module (DIMM) slot, peripheral component interconnect express (PCI-E) slot or universal serial bus (USB) slot, and so on; however, these examples are merely for exemplary illustration, and the application field of the present disclosure is not limited to these examples.

In an embodiment, as shown in FIG. 3A, the connector slot connector 21 of the connector slot detection circuit board 20 is the DIMM connector, and the connector slot detection circuit board 20 is provided with a connector slot connector 21, an input joint test action group (JTAG) connector 22, an output JTAG connector 23, a JTAG chip 24 and a microprocessor 25.

According to this embodiment, in the step 102, the connector slot detection circuit board 20 is plugged on the connector slot 11 of the to-be-detected circuit board 10 by the connector slot connector 21, and the microprocessor 25 is electrically connected to the connector slot connector 21 and the JTAG chip 24, and the JTAG chip 24 is electrically connected to the input JTAG connector 22 and the output JTAG connector 23.

In another embodiment, as shown in FIG. 3B, the connector slot connector 21 of the connector slot detection circuit board 20 is the PCI-E connector, and the connector slot detection circuit board 20 is provided with the connector slot connector 21, the input JTAG connector 22, the output JTAG connector 23, the JTAG chip 24 and at least one analog to digital converter (ADC) 26.

According to this embodiment, in the step 102, the connector slot detection circuit board 20 is plugged on the connector slot 11 of the to-be-detected circuit board 10 by the connector slot connector 21, and the at least one ADC 26 is electrically connected to the connector slot connector 21 and the JTAG chip 24, and the JTAG chip 24 is electrically connected to the input JTAG connector 22 and the output JTAG connector 23.

In another embodiment, as shown in FIG. 3C, the connector slot connector 21 of the connector slot detection circuit board 20 is the USB connector, and the connector slot detection circuit board 20 is provided with the connector slot connector 21, the input JTAG connector 22, the output JTAG connector 23, the JTAG chip 24 and the switch 27.

According to this embodiment, in the step 102, the connector slot detection circuit board 20 is plugged on the connector slot 11 of the to-be-detected circuit board 10 by the connector slot connector 21, and the switch 27 is electrically connected to the connector slot connector 21, the JTAG chip 24 and the input JTAG connector 22, and the JTAG chip 24 is electrically connected to the input JTAG connector 22 and output JTAG connector 23.

Next, in the step 103, the TAP controller 30 is electrically connected to the input JTAG connector 22 of one of the two connector slot detection circuit board 20. In the step 104, the output JTAG connector 23 of the one of the two connector slot detection circuit boards 20 is electrically connected to the input JTAG connector 22 of the other of the two connector slot detection circuit boards 20.

In the step 105, the TAP controller 30 sets the JTAG chip 24 of the one of the two connector slot detection circuit boards 20 to be in a boundary scan mode, and when the connector slot connector 21 of the one of the two connector slot detection circuit boards 20 testing the to-be-detected circuit board 10 is the PCI-E connector, the JTAG chip 24 of the one of the two connector slot detection circuit boards 20 is further set in an EXTEST mode, and the JTAG chip 24 of the other of the two connector slot detection circuit boards 20 which does not test the to-be-detected circuit board 10 is set in a BYPASS mode.

After the aforementioned setting step, in the step 105, the TAP controller 30 transmits a control signal to the JTAG chip 24 the one of the two connector slot detection circuit boards 20, and the JTAG chip 24 of the one of the two connector slot detection circuit boards 20 reads at least one detection signal corresponding to at least one detection pin of the connector slot connector 21 via the one of the microprocessor 25, the switch 27 and the at least one ADC 26. For example, the at least one detection pin can be a power pin, a ground pin, an I/O pin, a differential I/O pin, and so on; however, these examples are merely for exemplary illustration, and the application field of the present disclosure is not limited thereto. The JTAG chip 24 of the one of the two connector slot detection circuit boards 20 can transmit the at least one detection signal to the TAP controller 30. According to the at least one detection signal provided by the JTAG chip 24 of the one of the two connector slot detection circuit boards 20, the TAP controller 30 can perform a conduction detection on at least one pin of the at least one connector slot 11 corresponding to the at least one detection signal.

During the process of searching a motherboard schematic diagram to determine a target pin to be tested, all interfaces on entire scan chain are processed uniformly; and during the process of collecting parameters and testing, all interfaces on the scan chain are classified upon interface types. During the test process, the jigs in the scan chain and not joined in the test process are applied by a boundary scan BYPASS command, so as to ensure that all test jigs plugged on one scan chain can be tested with a high coverage, thereby saving test time and achieving the test efficiency the same as the test efficiency of testing with multiple chains which is the one scan chain is split into.

To summary, the difference between the technology of the present invention and conventional technology is that, in the system and method of the present invention, the connector slot detection circuit board is plugged on the connector slot of the to-be-detected circuit board, and the connector slot detection circuit boards including different types of connector slots are concatenated with each other, and the TAP controller sets the JTAG chip of the one of the two connector slot detection circuit boards to be in the boundary scan mode, and the JTAG chip of the one of the two connector slot detection circuit boards can read at least one detection signal corresponding to at least one detection pin of the connector slot connector via the one of the ADC, the microprocessor and the switch; and, according to the at least one detection signal provided by the JTAG chip of the one of the two connector slot detection circuit boards, the TAP controller can perform a conduction detection on the at least one pin of the connector slot corresponding to the at least one detection signal.

Above-mentioned technical means can be used to solve the problem that insufficient test efficiency and coverage for connector slot test on the circuit board in a conventional manner, so as to achieve improvement in test efficiency and coverage rate for testing the connector slot of the circuit board.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A pin conduction detection system for connector slot of circuit board, comprising:
a to-be-detected circuit board comprising at least one connector slot;
two connector slot detection circuit board each comprising a connector slot connector, an input joint test action group (JTAG) connector, an output JTAG connector, a JTAG chip, and one of a microprocessor (MCU), at least one analog to digital converter (ADC) and a switch, wherein the at least one ADC or the microprocessor is electrically connected to the connector slot connector and the JTAG chip, and the switch is electrically connected to the connector slot connector, the JTAG chip and the input JTAG connector, and wherein the JTAG chip is electrically connected to the input JTAG connector and the output JTAG connector;
a TAP controller electrically connected to the input JTAG connector of one of the two connector slot detection circuit boards;
wherein the output JTAG connector of the one of the two connector slot detection circuit boards is electrically connected to the input JTAG connector of the other of the two connector slot detection circuit boards, and the output JTAG connector of the other of the two connector slot detection circuit boards is used for series connection;
wherein the one of the two connector slot detection circuit boards is plugged on the at least one connector slot of the to-be-detected circuit board via its connector slot connector; and
wherein the TAP controller is configured to set the JTAG chip of the one of the two connector slot detection circuit boards to be in a boundary scan mode, and transmit a control signal to the JTAG chip of the one of the two connector slot detection circuit boards, and the JTAG chip of the one of the two connector slot detection circuit boards reads at least one detection signal corresponding to at least one detection pin of the connector slot connector via the one of the microprocessor, the switch and the at least one ADC, wherein according to the at least one detection signal provided by the JTAG chip of the one of the two connector slot detection circuit boards, the TAP controller performs a conduction detection on the at least one pin of the at least one connector slot corresponding to the at least one detection signal.

2. The pin conduction detection system according to claim 1, wherein the at least one connector slot comprises at least one dual in-line memory module (DIMM) slot, peripheral component interconnect express (PCI-E) slot, or universal serial bus (USB) slot.

3. The pin conduction detection system according to claim 1, wherein the connector slot connector comprises a DIMM connector, a PCI-E connector, or a USB connector.

4. The pin conduction detection system according to claim 1, wherein the at least one detection pin of the connector slot connector comprises at least one power pin, ground pin, I/O pin, or differential I/O pin.

5. The pin conduction detection system according to claim 1, wherein when the one of the two the connector slot detection circuit boards is testing the to-be-detected circuit board, the JTAG chip of the one of the two the connector slot detection circuit boards is further set in an EXTEST mode, and wherein the JTAG chip of the one of the two the connector slot detection circuit boards is further set in a BYPASS mode when the one of the two connector slot detection circuit boards is not testing the to-be-detected circuit board.

6. A pin conduction detection method for connector slot of circuit board, comprising:
providing a to-be-detected circuit board comprising at least one connector slot;
providing two connector slot detection circuit board each comprising a connector slot connector, an input JTAG connector, an output JTAG connector, a JTAG chip, and one of a microprocessor, at least one ADC and a switch, wherein the at least one ADC or the microprocessor is electrically connected to the connector slot connector and the JTAG chip, and the switch is electrically connected to the connector slot connector, the JTAG chip and the input JTAG connector, and wherein the JTAG chip is electrically connected to the input JTAG connector and the output JTAG connector;
providing a TAP controller electrically connected to the input JTAG connector of one of the two connector slot detection circuit boards;
wherein the output JTAG connector of one of the two connector slot detection circuit boards is electrically connected to the input JTAG connector of the other of the two connector slot detection circuit boards, and the output JTAG connector of the other of the two connector slot detection circuit boards is used for series connection;
wherein the one of the two connector slot detection circuit boards is plugged on the at least one connector slot of the to-be-detected circuit board via its connector slot connector; and
wherein the TAP controller sets the JTAG chip the one of the two connector slot detection circuit boards to be in a boundary scan mode, and transmit a control signal to the JTAG chip the other of the two connector slot detection circuit boards, and the JTAG chip of the one of the two connector slot detection circuit boards reads at least one detection signal corresponding to at least one detection pin of the connector slot connector via the one of the microprocessor, the switch and the at least one ADC, and according to the at least one detection signal provided by the JTAG chip of the one of the two connector slot detection circuit boards, the TAP controller performs a conduction detection on the at least one pin of the at least one connector slot corresponding to the at least one detection signal.

7. The pin conduction detection method according to claim 6, wherein the at least one connector slot comprises at least one DIMM slot, PCI-E slot, or USB slot.

8. The pin conduction detection method according to claim 6, wherein the connector slot connector comprises a DIMM connector, a PCI-E connector or a USB connector.

9. The pin conduction detection method according to claim 6, wherein the at least one detection pin of the connector slot connector comprises at least one power pin, ground pin, I/O pin, or differential I/O pin.

10. The pin conduction detection method according to claim 6, wherein when the one of the two the connector slot detection circuit boards is testing the to-be-detected circuit board, the JTAG chip of the one of the two the connector slot detection circuit boards is further set in an EXTEST mode, and wherein the JTAG chip of the one of the two the connector slot detection circuit boards is further set in a BYPASS mode when the one of the two connector slot detection circuit boards is not testing the to-be-detected circuit board.
